(19) United States
(12) Patent Application Publication
(10) Pub. No.: US 2006/0279754 A1
(43) Pub. Date: Dec. 14, 2006

(54) Image processing apparatus, image processing method, and image processing program product

(75) Inventor: Jun Minakuti, Sakai-shi (JP)

Correspondence Address: SIDLEY AUSTIN LLP, 717 NORTH HARWOOD, SUITE 3400, DALLAS, TX, 75201, US

(73) Assignee: KONICA MINOLTA PHOTO IMAGING, INC.

(21) Appl. No.: 11/314,763

(22) Filed: Dec. 21, 2005

(30) Foreign Application Priority Data
Jun. 10, 2005 (JP) 2005-171490

(51) Int. Cl. G03F 3/08

(52) U.S. Cl. 358/1.9; 358/518

(57) ABSTRACT

A set value input screen used for a user to input set values is displayed on a display unit for parameters when a manual setting mode is set. A list box of the set value input screen is for designating an arbitrary object to be set out of the parameters, and a graph display-input portion displays a graph representation of initial values of the set value at a plurality of points of time set beforehand and having specified intervals therebetween for the parameter selected in the list box. Data points at the respective points of time are movable by an input unit and the set values corresponding to the data points can be changed by moving the data points. There can be provided highly versatile image processing apparatus and image processing program matching human visual characteristics while preventing or suppressing a cost increase and a larger-scale construction.

This application is based on Japanese Patent Application No. 2005-171490 filed on Jun. 10, 2005, the contents of which are hereby incorporated by reference.

### BACKGROUND OF THE INVENTION

1. Field of the Invention

This invention relates to an image processing technology for performing image processing using a color appearance model.

2. Description of the Related Art

Color conversions using a color appearance model have been conventionally known as disclosed, for example, in Japanese Unexamined Patent Publication Nos. 2001-60082, 2001-258044 and 2003-323610.

The first publication discloses a technology that a color reproduction characteristic of a display device and an illumination condition at the time of viewing an image on the display device are obtained by means of a color camera, a color conversion including an adaptive correction is applied to images obtained via a network based on the color reproduction characteristic and the illumination condition during the viewing, and the resulting image is displayed on the display device.

The second publication discloses a medical image processing technology that a photographed image of an affected area is converted into an output image which is to be reproduced in colors viewed under a desired illumination using an illumination condition around a display device and a color characteristic of the display device, and the image after the conversion is displayed on the display device.

The third publication discloses a technology that a reference color light is projected onto a projection surface, a reflected light at this time is sensed by a color sensor, and the color of an image to be projected onto the projection surface in accordance with an output signal of the color sensor is corrected in order to match the color appearances of an image projected by a projector in different viewing environments.

However, in the technologies of the above first to third publications, it is necessary to install the camera or the sensor to obtain an ambient environment of the display device or the projection surface together with the image processing apparatus for performing the color conversion, the display device and the like. This is thought to lead to a large scale construction for performing the color conversion, a considerable cost and a reduction in versatility.

In the conventional color conversion using a color appearance model, if display devices are often used in an office, only one parameter supposing the installation environment of a general display in the office, and the color conversion is constantly performed using this parameter. Thus, the color conversion could be performed only using the parameter set beforehand for a specific environmental condition in which images are to be viewed.

### SUMMARY OF THE INVENTION

It is an object of the present invention to provide a novel technology which is free from the problems residing in the prior art.

According to an aspect of the present invention, an image processing is carried out by performing a color conversion using a color appearance model. The color conversion uses parameters, at least one of which is expressed as a function of time. An image processing apparatus is provided with a color converter for performing a color conversion using parameters, at least one of which is expressed as a function of time.

The inventive image processing apparatus and method make it possible to have a higher versatility, and match human visual characteristics while preventing or suppressing a cost increase and a larger-scale construction.

These and other objects, features, aspects and advantages of the present invention will become more apparent upon a reading of the following detailed description and accompanying drawings.

### BRIEF DESCRIPTION OF THE DRAWINGS

FIG. 1 is a diagram showing an electrical construction of an image processing apparatus according to an embodiment of the invention;

FIG. 2 is a diagram showing parameters set in a CIECAM97s used in the embodiment;

FIG. 3 is a flowchart showing a mode setting routine by a mode setting section of the image processing apparatus;

FIG. 4 is a flowchart showing a setting mode processing by a setting mode processing section in Step #104 of the flowchart shown in FIG. 3;

FIG. 5 is a diagram showing one example of a set value input screen displayed on a display unit;

FIG. 6 is a diagram showing one example of a set value correction screen display on a display unit;

FIG. 7 is a flowchart showing an execution mode processing by an execution mode processing section in Step #106 of the flowchart shown in FIG. 3;

FIG. 8 is a flowchart showing an operation in Step #301 of the flowchart shown in FIG. 7,

FIG. 9 is a diagram showing another example of the set value input screen displayed on a display device; and

FIG. 10 is a diagram showing still another example of the set value input screen displayed on a display device.

### DETAILED DESCRIPTION OF THE PREFERRED EMBODIMENTS OF THE INVENTION

A preferred embodiment of an image processing apparatus according to an embodiment of the present invention is described.

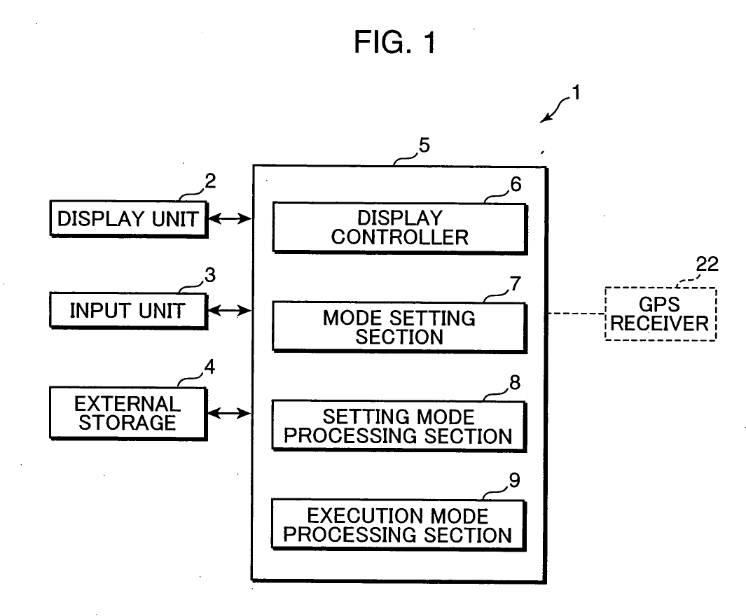

Referring to FIG. 1 showing an electrical construction of an image processing apparatus embodying the present invention, an image processing apparatus 1 includes a display unit 2, an input unit 3, an external storage 4, a control unit 5. The image processing apparatus has a construction similar to a personal computer or PC.

The display unit 2 includes a CRT (cathode-ray tube), an LCD (liquid crystal display), a PDP (plasma display panel) or the like for displaying images and various other data. The input unit 3 is responsive to a keyboard and/or a mouse, for example to input instructions to cause the control unit 5 as described later and the like to perform desired processings and operations, and various data.

The external storage 4 includes, for example, a hard disk for saving images photographed by an electronic camera, a scanner, a digital video movie camera or the like and read from these devices via a memory card reader, a USB, an IEEE1394 or the like interface; images read from a storage medium such as a DVD via a disk driver; and images obtained via Internet. The image processing apparatus is applicable for processing of any digitalized image data regardless of the kinds of hardware used to obtain images, the kinds of images, i.e., still images or moving images, the kinds of file format, interface and storage medium.

The control unit 5 includes a microcomputer having a built-in internal storage for storing, for example, a control program. The control program stored in the control unit 5 includes an application program using a color appearance model.

The color appearance model is a mode used to predict the appearance of colors by a visual system, wherein numerical values corresponding to senses such as brightness, saturation and hue are calculated using color specification values and parameters corresponding to viewing conditions. For example, a Lab model, a Naya model, a Hunt model, a RLab model and a LLab model have been proposed as color appearance models. In recent years, CIECAM97s and CIECAM02 recommended by the CIE (organization for setting standards on color, abbreviation of International Commission on Illumination) have been increasingly used as standard models. In this embodiment, out of these color appearance models, the CIECAM97s is used below.

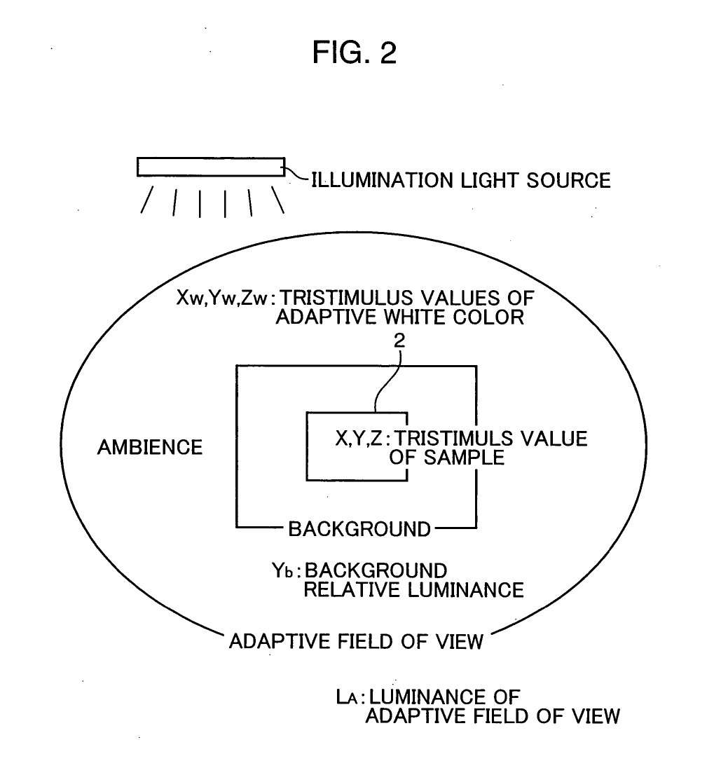

In the CIECAM97s, a luminance L_{A} of an adaptive field of view, a background relative luminance Yb, and tristimulus values Xw, Yw, Zw of an adaptive white color are set as parameters for the brightness of an environment where the display screen of the display unit 2 as a viewing object is disposed and the color of an illumination light source as shown in FIG. 2. Further, an impact of surround: c, a chromatic induction factor: Nc, a lightness contrast factor: F_{LL} and a factor for degree of adaptation: F are set as factors for determining the influences of the above parameters.

This embodiment is characterized in that the above parameters L_{A}, Yb, Xw, Yw and Zw are set as a function of time, thereby adding the CIECAM97s model with a function of performing a color conversion in conformity with a point of time when an image saved in the external storage 4 is displayed on the display unit 2.

The control unit 5 functions as a display controller 6, a mode setting section 7, a setting mode processing section 8 and an execution mode processing section 9 by the aforementioned application program. Hereinafter, this application program is referred to as an image processing program.

The display controller 6 is adapted for causing various setting screens and images after the color conversion to be displayed on the display unit 2.

The mode setting section 7 is adapted for setting a mode inputted by an operator on an unillustrated mode setting screen displayed on the display unit 2. This embodiment has a setting mode and an execution mode described below. The setting mode is a mode for setting values of the respective parameters set in the CIECAM97s, whereas the execution mode is a mode for applying a color conversion to an image based on the values set in the setting mode.

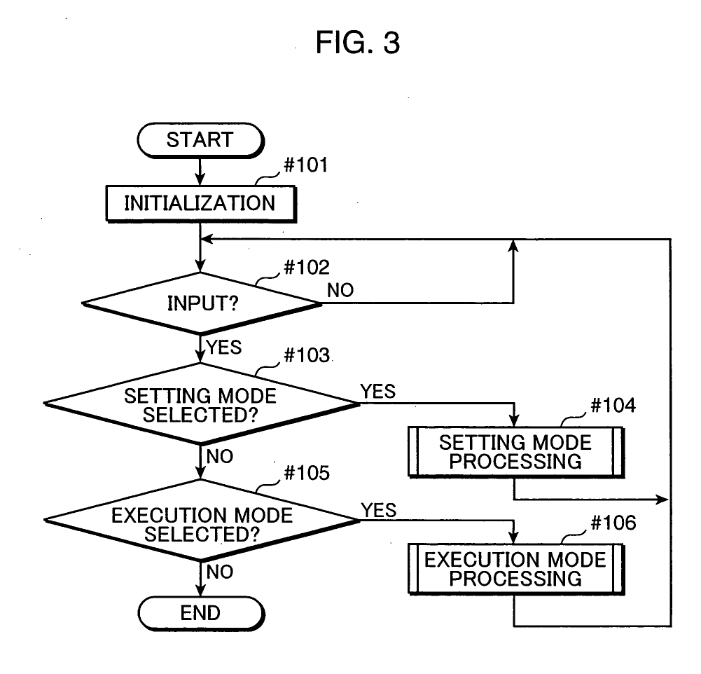

A mode setting routine by the mode setting section 7 is described below. FIG. 3 is a flowchart showing the mode setting routine by the mode setting section 7.

As shown in FIG. 3, when the image processing program is started, the mode setting section 7 initializes variables, flags and the like to be used (Step #101). Then, the mode setting section 7 waits on standby until a certain input is made by the input unit 3 (NO in Step #102). When a certain input is made by the input unit 3 (YES in #102), the mode setting section 7 judges the content of the input (Step #103).

If the content of the input is the selection of the setting mode (YES in Step #103), the mode setting section 7 causes the setting mode processing section 8 to execute a setting mode processing to be described later (Step #104). If the content of the input is the selection of the execution mode (NO in Step #103 and YES in Step #105), the mode setting section 7 causes the execution mode processing section 9 to execute the execution mode processing to be described later (Step #106). If the content of the input is neither the selection of the setting mode nor the selection of the execution mode, i.e., an instruction to end (NO in Steps #103, #105), a series of processings are ended.

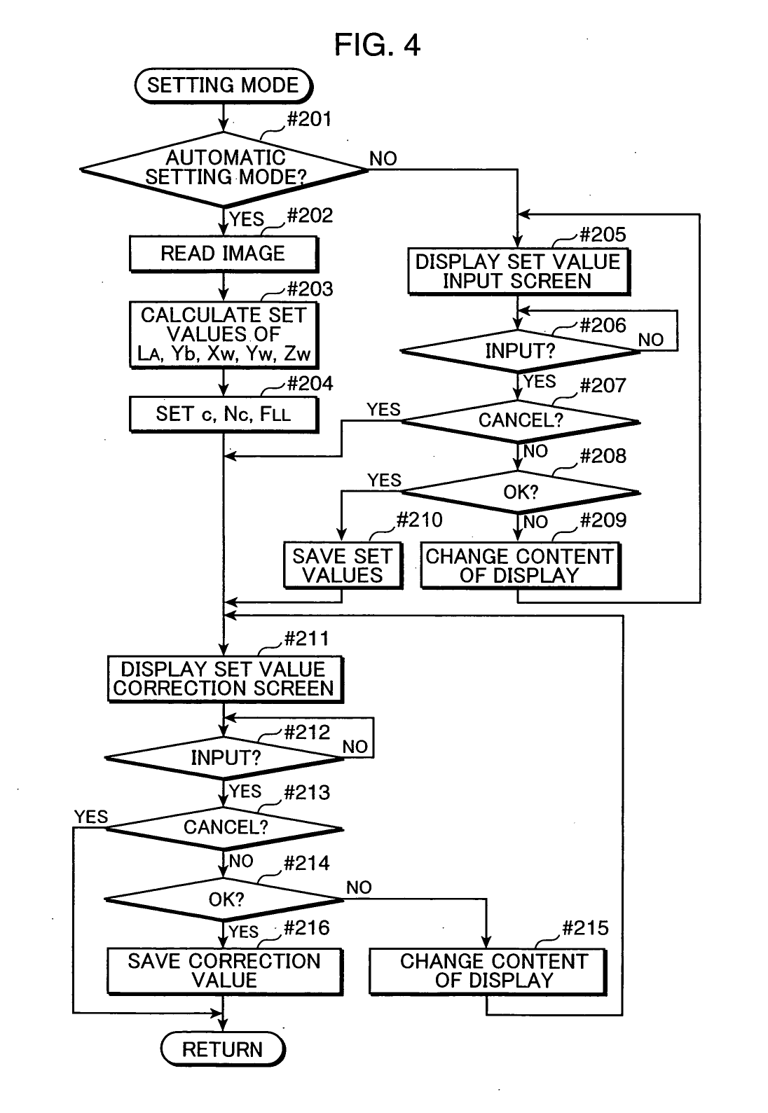

FIG. 4 is a flowchart showing the setting mode processing by the setting mode processing section 8 in Step #104.

As shown in FIG. 4, the setting mode processing section 8 judges whether an automatic setting mode or a manual setting mode is set (Step #201). In this embodiment, a plurality of images obtained by photographing the display unit 2 and subjects surrounding the display unit 2 in correspondence with different points of time or different dates, for example, by means of an electronic camera are stored or saved in the external storage 4. The automatic setting mode is a mode in which these photographed images are read from the external storage 4 and set values for the parameters are automatically derived from the photographed images. The manual setting mode is a mode in which a user inputs set values for the parameters in correspondence with different dates. Further, in this embodiment, it is assumed that the photographed images are saved in the external storage 4 in the form of RAW data, and are photographed by means of an electronic camera.

If the automatic setting mode is set (YES in Step #201), the setting mode processing section 8 reads the photographed images from the external storage 4 (Step #202) and derives the necessary parameters L_{A}, Yb, Xw, Yw and Zw from these photographed images as follows (Step #203).

First, the setting mode processing section 8 calculates the luminance L_{A} of the adaptive field of view from a proper exposure value (control luminance) of the electronic camera related to the image data. The proper exposure value is recorded by a Bv value of an APEX system, and the setting mode processing section 8 converts this Bv value into a luminance L_{A}(cd/mm²) by the following Equation (1):
L_{A}=2^{BV}·K·N (1)
wherein K denotes a calibration constant (=14) of an exposure meter and N denotes a constant (=0.3).

Subsequently, the setting mode processing section 8 calculates the background relative luminance Yb. The background relative luminance Yb is set in according with the following Equation (2) after an average luminance Bvc of pixels belonging to an area of a viewing angle of, e.g., 2 degrees from the center of the screen and an average luminance Bvb of pixels belonging to an area of a viewing angle of, e.g., 10 degrees from the center of the screen are calculated:
Yb=2^{Bvb}/2^{Bvc}×0.18×100 (2)

Here, the setting mode processing section 8 sets the background relative luminance Yb at “100” if the relative luminance Yb calculated in accordance with Equation (2) exceeds “100”. It should be noted that the areas of the viewing angles of 2 degrees and 10 degrees can be determined based on a relation between an angle of field calculated from the size of the image pickup device provided in the electronic camera and a focal length of a lens used during the photographing operation, and the number of pixels of the image pickup device. Although the areas for the calculation of the average luminances Bvc, Bvb are areas of the viewing angles of 2 degrees and 10 degrees here, these areas may be settable by a user.

Subsequently, the setting mode processing section 8 calculates the tristimulus values Xw, Yw, Zw of the adaptive white color. The setting mode processing section 8 first calculates a color temperature value T of a light source from a R/G ratio and a B/G ratio of a photographic scene calculated and recorded by a white balance processing of the electronic camera in accordance with the following Equation (3):
1/T=A0−A1×ln[(B/G)/(R/G)] (3)
wherein A0, A1 denote constants determined by the spectral characteristic of the image pickup device.

Then, the setting mode processing section 8 calculates chromaticity values x, y of black radiation at the calculated color temperature value T by referring to a conversion table. Here, the setting mode processing section 8 sets the tristimulus values Xw, Yw, Zw in accordance with the following Equations (4) to (6) while setting reflectivity at 90%.
Xw=x×y/90 (4)
Yw=90 (5)
Zw=(1−x−y)×90 (6)

After the operation in Step #203, the setting mode processing section 8 calculates a contrast to a peripheral portion and sets the coefficients c, Nc, F_{LL}, F using this contrast (Step #204). The peripheral portion is a part outside a background part determined upon calculating the background relative luminance Yb. The setting mode processing section 8 calculates the area of the viewing angle of 10 degrees substantially by the same method for calculating the background relative luminance Yb, calculates an average luminance Bvs in an area located outside the area of the viewing angle of 10 degrees, and determines the coefficients c, Nc, F_{LL}, F from a difference between the average luminance Bvs and the average luminance Bvc.

Concerning these coefficients c, Nc, F_{LL}, F, recommended values as shown in TABLE-1 are set in accordance with viewing conditions in the CIECAM97s.

TABLE 1

| Viewing conditions | c | Nc | F_{LL} | F |
|---|---|---|---|---|
| Average peripheral portion, sample | 0.69 | 1.0 | 0 | 1.0 |
| angle of view is 4 or larger | | | | |
| Average peripheral portion | 0.69 | 1.0 | 1.0 | 1.0 |
| Dim peripheral portion | 0.59 | 1.1 | 1.0 | 0.9 |
| Dark peripheral portion | 0.525 | 0.8 | 1.0 | 0.9 |
| Slide film on a light box | 0.41 | 0.8 | 1.0 | 0.9 |

Accordingly, the setting mode processing section 8 judges the viewing condition as follows from the difference between the average luminances Bvs and Bvc, and sets values for the coefficients c, Nc, F_{LL}, F in accordance with TABLE-1.

Bvc—Bvs<0: average peripheral portion

Bvc—Bvs>2.7: dark peripheral portion

0≦Bvc—Bvs≦2.7: dim peripheral portion

For example, if Bvc—Bvs=“−1”, the setting mode processing section 8 judges that the peripheral portion is an “average peripheral portion” and sets “0.69”, “1”, “1”, and “1” as values for the coefficients c, Nc, F_{LL}, F corresponding to the “average peripheral portion” with reference to TABLE-1.

The viewing conditions are divided using values of (Bvc—Bvs) as boundaries here. It may be appreciated to calculate interpolating values of the coefficients c, Nc, F_{LL}, F corresponding to the values of (Bvc—Bvs) corresponding to the respective viewing conditions shown in TABLE-1.

The setting mode processing section 8 saves the above set values (“0.69”, “1”, “1”, and “1” in the above example) in the external storage 4 in relation to date information added to the photographed image. The setting mode processing section 8 carries out the above processing for all the photographed images at different points of time or different dates saved in the external storage 4, connects the calculated set values by a spline curve, and saves the spline curve of the parameter as a function of time in the external storage 4 in relation to the dates of photographing.

On the other hand, if the manual setting mode is judged to be selected in Step #201 (NO in Step #201), the display controller 6 and the setting mode processing section 8 carry out the following operations.

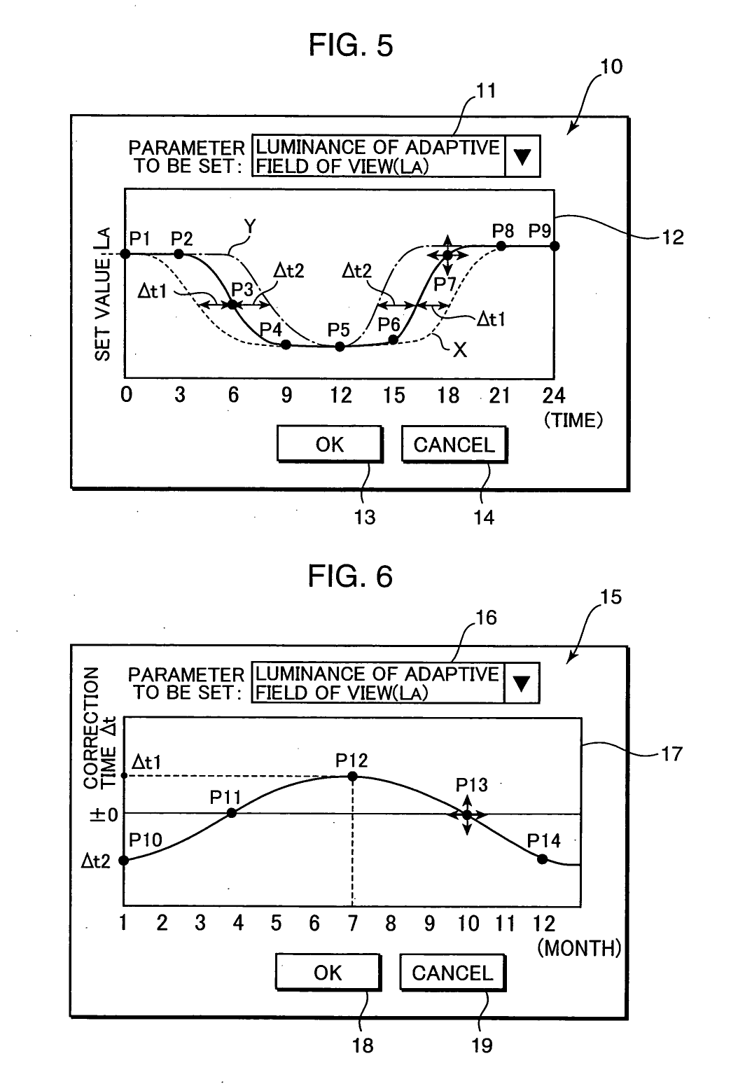

First, the display controller 6 causes a set value input screen used for the user to input set values for the respective parameters L_{A}, Yb, Xw, Yw and Zw to be displayed on the display unit 2, for example, as shown in FIG. 5 (Step #205).

A set value input screen 10 shown in FIG. 5 includes a list box 11 placed at the top, a graph display/input portion 12 placed substantially in the middle of the screen, an “OK” button 13 placed below the graph display/input portion 12 for the input confirmation of the set content, and a “CANCEL” button 14 for the erasure of the set content.

The list box 11 is for designating an arbitrary object to be set out of the respective parameters, i.e., the luminance L_{A} of the adaptive field of view, the background relative luminance Yb and the tristimulus values Xw, Yw, Zw of the adaptive white color. A list of the above parameters is displayed by operating a triangular symbol, and a specified operation is made to a display area of an arbitrary parameter in this list, whereby this operation object is set as a parameter to be set and the name of this parameter is displayed. In FIG. 5, the luminance L_{A} of the adaptive field of view is designated as a parameter to be set.

The graph display/input portion 12 displays initial values of set values at a plurality of points of time having specified intervals therebetween set beforehand in the form of a graph for the parameter selected in the list box 11. Data points P1 to P9 at the respective points of time in this graph are movable by means of the input unit 3, and the set values corresponding to the data points P1 to P9 can be changed by moving the data points P1 to P9. It should be noted that, on this screen, the respective data points P1 to P9 are interpolated by spline curves to represent the set values for the parameter as a function of time.

The setting mode processing section 8 judges whether or not any input has been made to this set value input screen 10 (Step #206), and waits on standby if no input has been made (NO in Step #206) while judging whether or not the content of the input is an input operation made to the “CANCEL” button 14 (Step #207) if an input has been made (YES in Step #206). The setting mode processing section 8 proceeds to Step #211 if the content of the input is the input operation to the “CANCEL” button 14 (YES in Step #207) while judging whether or not the content of the input is an input operation made to the “OK” button 13 (Step #208) if it is not the input operation to the “CANCEL” button 14 (NO in Step #207). If the content of the input is not the input operation made to the “OK” button 13, i.e., it is a change of the parameter in the list box 11 or a change of the position of the data point P1 to P9 in the above graph (NO in Step #208), the setting mode processing section 8 returns to Step #205 after changing the display content (Step #209). If the content of the input is the input operation made to the “OK”button 13 (YES in Step #208), the setting mode processing section 8 proceeds to Step #211 after saving the content inputted on the set value input screen 10 in the external storage 4 (Step #210).

The display controller 6 displays a set value correction screen 15, for example, as shown in FIG. 6 (Step #211) after the operation in Step #204, #207 or #210.

The set value correction screen 15 shown in FIG. 6 is a screen used to correct the set values for the respective parameters, i.e., the luminance L_{A} Of the adaptive field of view, the background relative luminance Yb and the tristimulus values Xw, Yw, Zw of the adaptive white color in accordance with month, and includes a list box 16 placed at the top, a correction value display/input portion 17, an “OK” button 18 for the input confirmation of the set content, and a “CANCEL” button 19 for the erasure of the set content.

The list box 16, the “OK” button 18 and the “CANCEL” button 19 are not described because their functions are substantially the same as those on the set value input screen 10 shown in FIG. 5.

The correction value display/input portion 17 displays an initial value of a correction time Δt in every month (January to December) set beforehand for the set value for the parameter selected in the list box 16. Data points P10 to P14 of specified months in this graph are movable by means of the input unit 3, and the correction time Δt of the month can be inputted by moving the data points P10 to P14. On the set value correction screen 15 shown in FIG. 6, the set value for the luminance L_{A} Of the adaptive field of view is selected as a parameter to be corrected.

The correction time Δt corresponds, for example, to a correction amount of the graph displayed on the set value input screen 10 (graph display/input portion 12) shown in FIG. 5. It is, for example, assumed that a solid-line graph of FIG. 5 represents April, April and October serve as a reference (correction value 0) as shown in FIG. 6, and a correction time “Δt1” is set for July based on this reference value and a correction time “Δt2” is set for January based on this reference value.

In this case, the width of the trough of the graph of April is widened to left and right by Δt1 in a graph of July as shown in dotted line “X” in FIG. 5, whereas the width of the trough of the graph of April is narrowed inwardly at both left and right sides by Δt2 in a graph of January as shown in phantom line “Y” in FIG. 5.

The set values for the respective parameters are corrected in accordance with month in this way because daylight conditions (e.g., radiation time of external light, angle of radiation, etc.) differ depending on the month and the season. Therefore, suitable values in conformity with the daylight conditions can be set.

The setting mode processing section 8 judges whether or not any input has been made to this set value correction screen 15 (Step #212), and waits on standby if no input has been made (NO in Step #212) while judging whether or not the content of the input is an input operation made to the “CANCEL” button 19 (Step #213) if an input has been made (YES in step #212). The setting mode processing section 8 ends the processing if the content of the input is the input operation to the “CANCEL” button 19 (YES in Step #213) while judging whether or not the content of the input is an input operation made to the “OK” button 18 (Step #214) if it is not the input operation to the “CANCEL” button 19 (NO in Step #213). If the content of the input is not the input operation made to the “OK” button 18, i.e., it is a change of the parameter in the list box 16 or a change of the position of the data point P10 to P14 in the above graph (NO in Step #214), the setting mode processing section 8 returns to Step #211 after changing the display content (Step #215). If the content of the input is the input operation made to the “OK” button 18 (YES in Step #214), the setting mode processing section 8 ends the processing after saving the correction time At inputted on the set value correction screen 15 in the external storage 4 (Step #216).

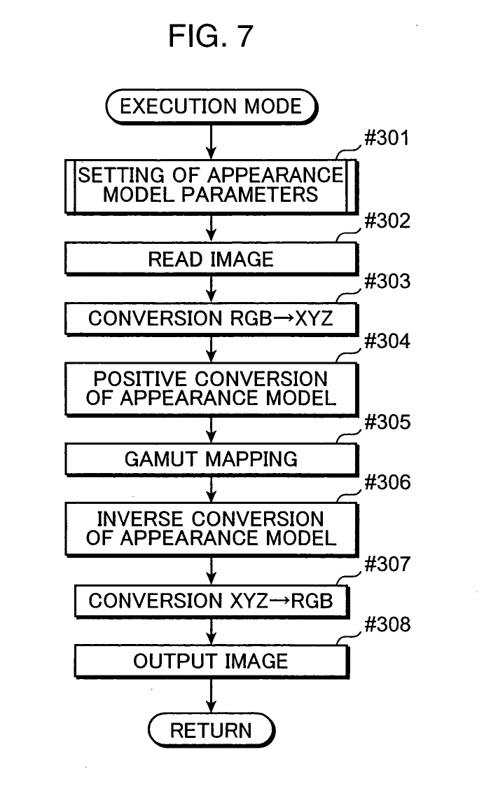

FIG. 7 is a flowchart showing the execution mode processing by the execution mode processing section 9 in Step #106. As shown in FIG. 7, the execution mode processing section 9 sets parameters necessary for the color appearance model to be described later (Step #301).

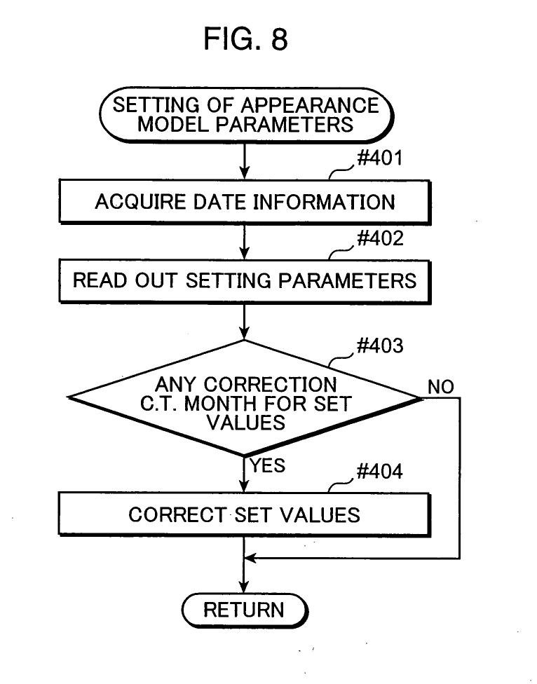

FIG. 8 is a flowchart showing the operation in Step #301 of the flowchart shown in FIG. 7.

As shown in FIG. 8, the execution mode processing section 9 first acquires the current date (time) information (Step #401), and reads out the respective set values for the parameters L_{A}, b, Xw, Yw and Zw from the external storage 4 in the CIECAM97s given as the functions of time using the obtained pieces of information (Step #402).

Subsequently, the execution mode processing section 9 judges whether or not the correction times in conformity with month are set for the set values (Step #403). Step #302 of the flowchart shown in FIG. 7 follows if no correction time has been set (NO in Step #403), whereas the set values are corrected (Step #404) if the correction times have been set (YES in Step #403). The correction made here means, for example, such a correction from the solid-line graph of FIG. 5 to the dotted-line or phantom-line graph of FIG. 5 as described above.

After the operation in Step #301, the execution mode processing section 9 reads a image to be processed from the external storage 4 (Step #302) and converts the read image into color specification values (Step #303) as shown in FIG. 7. In other words, the execution mode processing section 9 converts the image represented by RGB values into XYZ values by the XYZ color specification system.

Many images are represented by RGB values which are called a standard color space and whose relationship with the color specification values is defined. For example, many of images photographed by electronic cameras and those on Internet are represented by the standard color space called sRGB values. Accordingly, these images can be easily converted into color specification values by performing a conversion in accordance with the sRGB definition.

Further, images to be viewed on televisions are represented by RGB values in accordance with a standard television system in each country, and the relationship of the RGB values with the color specification values is also defined. For example, since images are generated in accordance with the NTSC system in Japan, they can be easily converted into color specification values. For images not represented in the standard color spaces, profiles representing the characteristics of these images are frequently provided while being paired with the images with the recent spread of the color management system. Accordingly, these images can be easily converted into color specification values using this profile information.

The profile information is standardized to a format called an ICC profile standardized by the ICC (International Color Consortium) which is a voluntary organization of the apparatus-related industries. Even in such a case where the profile is not provided while being paired with the image, there exists means capable of measuring an apparatus having generated this image and generating an ICC profile.

In this embodiment, the images represented by the RGB values are converted into the XYZ values by the XYZ color specification system of the CIE since it is preferable to use the XYZ values for the input to the color appearance model. However, the present invention is not limited thereto and optimal color specification values may be selected in view of the relationship with the color appearance model.

Subsequently, the execution mode processing section 9 converts the XYZ values after the conversion, for example, into brightness J, chroma c, and a hue angle h using the CIECAM97s with the read out parameters L_{A}, Yb, Xw, Yw and Zw(Step #304). In this conversion, by setting a suitable viewing condition for the inputted image, the brightness J, the chroma c and the hue angle h corresponding to the set viewing condition can be calculated.

The suitable viewing condition for an image corresponds to a viewing condition when a person sees a photographed scene in the case of an image obtained by photographing a certain scene by means of an electronic camera. In this embodiment, a set value for the viewing condition suitable for the image is added as a metadata to the image. In the case of a still image, one kind of parameter is added. In the case of moving images, one kind of parameter usable as a standard throughout the entire images or a plurality of parameters corresponding to a view variation are recorded. A converting method disclosed in the “CIE Technical Report, The CIE 1997 Interim Color Appearance Model (Simple Version), CIECAM97s, 1998” can be adopted as a detailed conversion method by the CIECAM97s.

Subsequently, the execution mode processing section 9 carries out gamut mapping (Step #305). The gamut mapping is a processing to map unreproducible colors within a reproduction range in the case that the color range of an inputted image is wider than the color reproduction range (gamut) of the display unit 2. For example, a method for uniformly compressing the image in directions of lightness and saturation in accordance with information on the color reproduction range of the display unit 2 or a method for setting a certain threshold value for pixel values and compressing the pixel values exceeding this threshold value within the color reproduction range can be adopted as a gamut mapping method.

Subsequently, the execution mode processing section 9 converts the brightness J, the chroma c and the hue angle h after the gamut mapping into color specification values (XYZ values) by an inverse model of the color appearance model (Step #306). These color specification values are adapted for giving a color appearance equivalent to the one when the image saved in the external storage 4 is directly viewed.

Subsequently, the execution mode processing section 9 converts the inversely-converted color specification values into RGB values, which are values peculiar to the display unit 2 (Step #307). It should be noted that, as in Step #303, if the display unit 2 receives an image by the standard color space such as sRGB, the color specification values can be converted into RGB values by an inverse conversion in conformity with the definition of the standard color space. If the characteristics of the display unit 2 are given by the ICC profile, the color specification values can be converted in accordance with these characteristics. After the operation in Step #307, the RGB values after the conversion are outputted to the display unit 2 (Step #308).

Although the display unit 2 is supposed as an image output apparatus in this embodiment, processings similar to the above can be easily carried out even in the case of a printer that receives CMY values and CMYK values provided that the characteristics of the printer are known and can be inversely converted.

As described above, the function of performing a color conversion in accordance with time is added to the CIECAM97s in the case that the parameters L_{A}, Yb, Xw, Yw and Zw are set as functions of time and the image saved in the external storage 4 is displayed on the display unit 2. Thus, images better matching the human visual characteristics can be obtained and the appearance of the image outputted by the display unit 2 can be refrained from largely differing depending on the ambient environment of the installed position of the display unit 2.

Further, as compared to the conventional construction in which an electrical camera or a sensor is installed for photographing the ambient environment of a display or a projection surface, there can be realized highly versatile image processing apparatus and image processing program while preventing or suppressing a cost increase and a larger-scale construction.

Furthermore, since the above functions are set by the set values for the parameters L_{A}, Yb, Xw, Yw and Zw preset for a plurality of points of time, suitable functions in conformity with time can be relatively easily set.

Further, since the set values for the parameters L_{A}, Yb, Xw, Yw and Zw are automatically derived from a plurality of images obtained by photographing the display unit 2 and the subject around it at temporally shifted timings, for example, by means of an electronic camera, the suitable set values can be derived in a labor-saving manner for the user.

Furthermore, since the set values for the respective parameters are corrected in accordance with month, images conforming to the ambient environment of the display unit 2 and better matching the human visual characteristics can be obtained. As a result, the appearance of the image outputted from the display unit 2 can be more refrained from largely differing depending on the ambient environment of the installed position of the display unit 2.

In addition to or instead of the above embodiments, the present invention can be modified into the following configurations (1) to (6).

(1) The set value input screen 10 shown in FIG. 5 of the first embodiment is merely one example, and set value input screens as described below may be, for example, adopted.

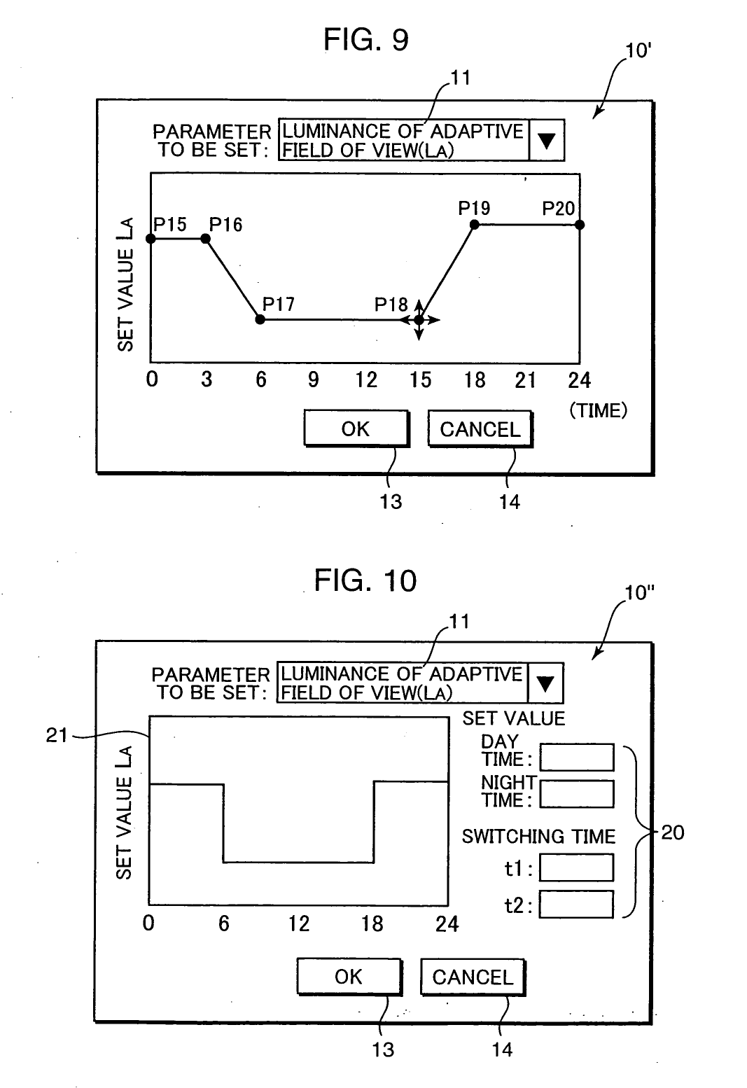

A set value input screen 10′ shown in FIG. 9 differs from the set value input screen 10 shown in FIG. 5 only in that data points P15 to P20 are interpolated by straight lines, but is substantially similar in other points.

A set value input screen 10″ shown in FIG. 10 is an example in which set values for the above parameters L_{A}, Yb, Xw, Yw and Zw are switched at two boundary times (in FIG. 10 daytime set values between 6:00 AM and 6:00 PM and nighttime set values between 6:00 PM and 6:00 AM). The set value input screen 10″ includes an input content display portion 20 for numerically displaying the set values for daytime and nighttime inputted by a user for the parameter selected in the list box 11 and switching times t1, t2 (hereinafter, these are referred to as input contents) of the set values, and a graph display portion 21 arranged adjacent to the input content display portion 20 for displaying the input contents in the form of a graph.

In FIGS. 9 and 10, the list box, “OK” button and the “CANCEL” button having substantially the same functions as those shown in FIG. 5 are identified by the same reference numerals 11, 13 and 14, respectively.

As shown in FIGS. 5, 9 and 10, optimal parameters can be set by discretely inputting the set values in relation to time to switch the set values in accordance with time and interpolating the data between adjacent ones of the data points P1 to P9 and between adjacent ones of the data points P15 to P20. Besides the switch of the data points and the interpolation as above, an extrapolation or an approximation equation may be used or these methods may be properly used for the respective data sections. In other words, method(s) may be set according to the purpose.

(2) Weather detecting means for detecting the weather by detecting, for example, an amount of sunlight may be provided, and the above set values may be changed in accordance with the detected weather.

(3) A GPS receiver 22 may be, for example, installed in the image processing apparatus 1 as shown in FIG. 1. The GPS receiver 22 may receive a signal from an unillustrated GPS satellite, detect the latitude and longitude of a place where the image processing apparatus 1 is used, and set correction values for the set values for the respective parameters in accordance with the detected latitude and longitude.

Even if the image processing apparatus 1 is not provided with the GPS receiver 22, the latitude and longitude of the place where the image processing apparatus 1 is used may be, for example, roughly calculated based on a time difference between the time in the installed placed of the image processing apparatus 1 and the Greenwich mean time or the country, area, capital city, city or the like to which the installed place of the image processing apparatus 1 belongs; the sunset time may be calculated based on the calculated latitude and longitude and the date; and the above correction values may be calculated based on the sunset time. It should be noted that the measuring means for measuring the installed place of the image processing apparatus is not limited to the GPS, and other measuring means may be used.

(4) In the first embodiment, if the contents (changes of the set values) changed by the inputting operation are reflected, for example, during the operation of inputting the set values, the operability of the inputting operation decreases. Thus, the contents changed by the inputting operation may be reflected after an instruction to end the display of the set value input screen.

(5) Notification or warning may be given to the user if the set values inputted on the set value input screen largely differ from those before setting. This processing may be carried out, for example, between Steps #208 and #210 shown in FIG. 4.

(6) In the foregoing embodiments, all the respective parameters L_{A}, Yb, Xw, Yw and Zw are expressed as the function of time. However, the intended technical performance may be accomplished by expressing at least one of these parameters as the function of time.

As described above, an image processing is carried out by performing a color conversion using a color appearance model. The color conversion uses parameters, at least one of which is expressed as a function of time.

An image processing apparatus is provided with a color converter for performing a color conversion using parameters, at least one of which is expressed as a function of time.

With the image processing apparatus and image processing method, parameters corresponding to an ambient environment of an image output apparatus for outputting an image after image processing by the image processing apparatus can be set since the color conversion is performed using the parameters, at least one of which is expressed as the function of time.

For example, if the image output apparatus is installed in a normal room, a user normally views images outputted by the image output apparatus in such a mixed environment of indoor illumination light and external light streaming in through a window. The external light mainly changes according to the altitude of the sun and the brightness of the room largely differs between daytime and nighttime. The indoor light may be constantly tuned on or may be turned on only at night. In either case, the difference in the brightness of the room results from a change of time, and an image viewing condition changes according to time. Thus, by performing the color conversion using the parameters, at least one of which is expressed as the function of time, the appearance of the images outputted from the image output apparatus can be refrained from largely differing depending on the ambient environment of the installed position of the image output apparatus.

Preferably, the function may include a function derived from a plurality of points of time and a plurality of set values for the parameters set beforehand for the respective points of time. Then, a suitable function corresponding to time can be relatively easily set.

Preferably, the function may include a function derived from set values for the parameters derived from a plurality of images including images of an image output apparatus for outputting images after image processing by the image processing apparatus and an ambient environment around an installed position of the image output apparatus and photographed at different points of time, and from dates and hours of photographing of the respective images. Then, the function can be automatically set. Accordingly, the user can save labor to set the function. It should be noted that the date and hour of photographing include both the date of photographing and the time of photographing.

Preferably, the image processing apparatus may further comprise a date information inputting device for inputting date information; a storage device for saving correction values for set values for the parameters, the correction values being set beforehand in correspondence with dates; and a corrector for, when the date information is inputted by the date information inputting device, reading the correction value corresponding to the date information from the storage device and correcting the set values for the parameters using the correction value.

With this construction, when the date information is inputted, the correction value corresponding thereto is read and the set values for the parameter are corrected using this correction value. Thus, more suitable images corresponding to the ambient environment at the installed position of the image output apparatus can be obtained. As a result, the appearance of the images outputted from the image output apparatus can be more refrained from largely differing depending on the ambient environment of the installed position of the image output apparatus.

Preferably, the image processing apparatus may further comprise an acquiring device for acquiring information on the latitude and/or longitude of an installed place of the image processing apparatus. Then, more suitable images corresponding to the ambient environment of the image output apparatus can be obtained. Specifically, if the latitude and/or longitude of the installed place of the image processing apparatus are known, it is possible to calculate the altitude of the sun and predict an average influence of the external light. Thus, by acquiring the information on the latitude and/or longitude of the installed place of the image processing apparatus, the appearance of the images outputted from the image output apparatus can be even more refrained from largely differing depending on the ambient environment of the installed position of the image output apparatus.

As this invention may be embodied in several forms without departing from the spirit of essential characteristics thereof, the present embodiment is therefore illustrative and not restrictive, since the scope of the invention is defined by the appended claims rather than by the description preceding them, and all changes that fall within metes and bounds of the claims, or equivalence of such metes and bounds are therefore intended to embraced by the claims.

What is claimed is:

1. An image processing apparatus for performing a color conversion using a color appearance model, comprising:
a color converter for performing a color conversion using parameters, at least one of which is expressed as a function of time.

2. An image processing apparatus according to claim 1, wherein the function includes a function derived from a plurality of points of time and a plurality of set values for the parameters set beforehand for the respective points of time.

3. An image processing apparatus according to claim 1, wherein the function includes a function derived from set values for the parameters derived from a plurality of images including images of an image output apparatus for outputting images after image processing by the image processing apparatus and an ambient environment around an installed position of the image output apparatus and photographed at different points of time, and from photographing dates of the respective images.

4. An image processing apparatus according to claim 1, further comprising:
a date information inputting device for inputting date information;
a storage device for saving correction values for set values for the parameters, the correction values being set beforehand in correspondence with dates; and
a corrector for reading the correction value corresponding to the date information from the storage device and correcting the set values for the parameters using the correction value, when the date information is inputted by the date information inputting device.

5. An image processing apparatus according to claim 1, further comprising an acquiring device for acquiring information on the latitude and/or longitude of an installed place of the image processing apparatus.

6. An image processing method for performing a color conversion using a color appearance model, comprising the step of:
executing a color conversion using parameters, at least one of which is expressed as a function of time.

7. An image processing method according to claim 6, wherein the function includes a function derived from a plurality of points of time and a plurality of set values for the parameters set beforehand for the respective points of time.

8. An image processing method according to claim 6, wherein the function includes a function derived from set values for the parameters derived from a plurality of images including images of an image output apparatus for outputting images after being processed, and an ambient environment around an installed position of the image output apparatus and photographed at different points of time, and from photographing dates of the respective images.

9. An image processing method according to claim 6, further comprising the steps of:
inputting date information;
saving correction values for set values for the parameters, the correction values being set beforehand in correspondence with dates; and
reading the correction value corresponding to the date information from the storage device and correcting the set values for the parameters using the correction value when the date information is inputted by the date information inputting device.

10. An image processing method according to claim 6, further comprising the steps of:
acquiring information on the latitude and/or longitude of an image processing place.
